(19) United States
(12) Patent Application Publication
(10) Pub. No.: US 2026/0160360 A1
(43) Pub. Date: Jun. 11, 2026

(54) PIPE LIMITING DEVICE AND SERVER CABINET USING THE SAME

(71) Applicant: LITE-ON TECHNOLOGY CORPORATION, Taipei (TW)

(72) Inventors: Zheng-Zong CHEN, Taipei (TW); Qi-Hong Yang, Taipei (TW); Hung-chi Hsu, Taipei (TW)

(21) Appl. No.: 19/292,953

(22) Filed: Aug. 7, 2025

Related U.S. Application Data
(60) Provisional application No. 63/728,210, filed on Dec. 5, 2024.

(30) Foreign Application Priority Data
May 6, 2025 (CN) 20250874548.2

(51) Int. Cl. F16L 5/00; H05K 7/20

(52) U.S. Cl. CPC F16L 5/00; H05K 7/20781

(57) ABSTRACT

A pipe limiting device is suitable for detachable connection to a cabinet body of a server cabinet. The pipeline limit device includes a first position-limiting element and a second position-limiting element. The first position-limiting element has a first limiting hole. The second position-limiting element has a second limiting hole and is detachably fixed to the first element. The first limiting hole partially overlaps with the second limiting hole.

This application claims the benefit of U.S. provisional application Ser. No. 63/728,210, filed Dec. 5, 2024, the subject matter of which is incorporated herein by reference, and claims the benefit of People's Republic of China application Serial No. 202520874548.2, filed on May 6, 2025, the subject matter of which is incorporated herein by reference.

### TECHNICAL FIELD

The disclosure relates in general to a pipe limiting device and a server cabinet using the same.

### BACKGROUND

A server cabinet may be equipped with a plurality of servers. In order to dissipate the generated heat when the servers are working, a cooling module is usually installed in the server cabinet. Therefore, how to secure the elements (e.g., pipes) of the cooling module has become an issue that needs to be considered by those skilled in the art.

### SUMMARY

According to an embodiment, a pipeline limiting device is provided. The pipeline limiting device is adapted to be detachably connected to a cabinet body of a server cabinet. The pipeline limiting device includes a first limiting element and a second limiting element. The first limiting element has a first limiting hole. The second limiting element has a second limiting hole and detachably fixed to the first limiting element. The first limiting hole and the second limiting hole partially overlap.

According to another embodiment, a server cabinet is provided. The server cabinet includes a cabinet body, a pipeline limiting device and a pipe. The pipeline limiting device is detachably connected to the cabinet body and includes a first limiting element and a second limiting element. The first limiting element has a first limiting hole. The second limiting element has a second limiting hole and is detachably fixed to the first limiting element, wherein the first limiting hole and the second limiting hole partially overlap. The pipe passes through an overlapping area where the first limiting hole and the second limiting hole overlap.

### BRIEF DESCRIPTION OF THE DRAWINGS

FIGS. 1A and 1B illustrate schematic diagrams of a server cabinet according to an embodiment of the present disclosure at different viewing angles;

FIG. 2 illustrates a schematic diagram of a cabinet body and a pipe limiting device of the server cabinet of FIG. 1A being separated;

FIG. 3 illustrates a schematic diagram of the pipe limiting device in FIG. 2 at another viewing angle;

FIGS. 4A to 4C illustrate schematic diagrams of exploded views of the pipe limiting device in FIG. 2 at different viewing angles;

FIG. 5A illustrates a schematic diagram of a front view of the pipe limiting device in FIG. 2 viewed along the −Z-axis;

FIG. 5B illustrates a schematic diagram of a cross-sectional view of the pipe limiting device in FIG. 5A along a direction 5B-5B′;

FIG. 5C illustrates a schematic diagram of a cross-sectional view of the pipe limiting device in FIG. 5A along a direction 50-5C′; and

FIG. 6 illustrates a schematic diagram of an expanded view of a first limiting element in FIG. 3.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

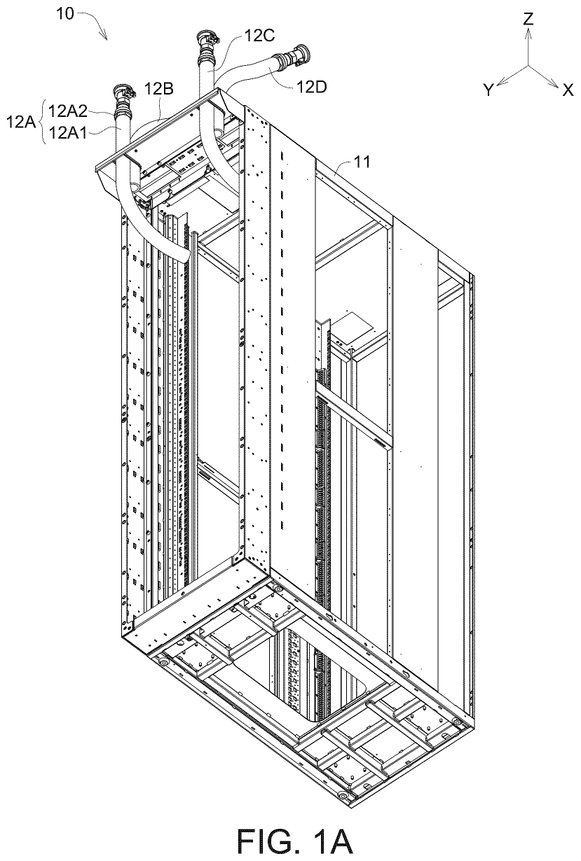

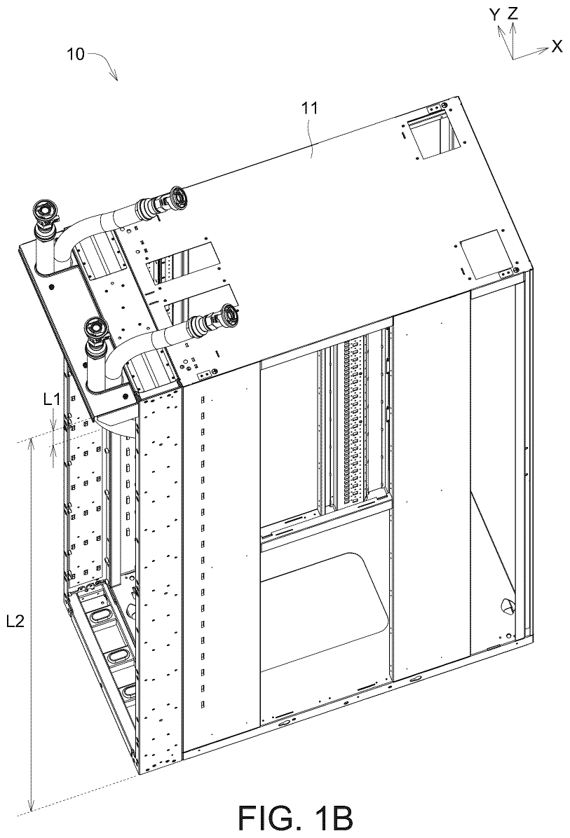

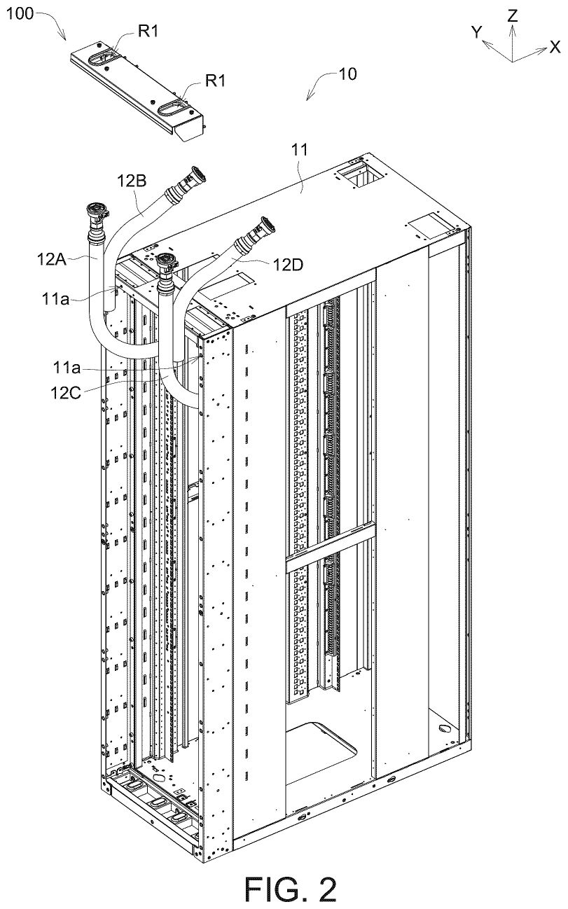

Referring to FIGS. 1A, 1B and 2, FIGS. 1A and 1B illustrate schematic diagrams of a server cabinet 10 according to an embodiment of the present disclosure at different viewing angles, and FIG. 2 illustrates a schematic diagram of a cabinet body 11 separated from a pipe limiting device 100 of the server cabinet 10 of FIG. 1A.

As shown in FIGS. 1A, 1B and 2, the server cabinet 10 includes a cabinet body 11, at least one pipe (e.g., a first pipe 12A, a second pipe 12B, a third pipe 12C and a fourth pipe 12D) and the pipe limiting device 100. The pipes may pass through the pipe limiting device 100, and the pipe limiting device 100 may constrain and/or secure the relative position of the pipes and the cabinet body 11. In the present embodiment, the pipe limiting device 100 is detachably connected to the cabinet body 11 to facilitate quick handling (e.g., disassembling or assembling) of the pipes. Since the length L1 of the pipe limiting device 100 along the Z-axis is much shorter than the length L2 of the cabinet body 11 along the Z-axis, it becomes easier to disassemble and/or assemble the pipe limiting device 100 (the longer the length L1 of the pipe limiting device 100 along the Z-axis, the more difficult it becomes to disassemble and/or assemble the pipe limiting device 100).

Although not shown, at least one server may be placed in the cabinet body 11. A cooling liquid (not shown) may flow through the pipes to absorb the heat of the servers in the cabinet body 11. The low-temperature cooling liquid may enter the cabinet body 11 through one or some of the pipes, absorb the heat of the server in the cabinet body 11, and then exit the cabinet body 11 through another one or some of these pipes. The cooling liquid is, for example, water or other types of liquids.

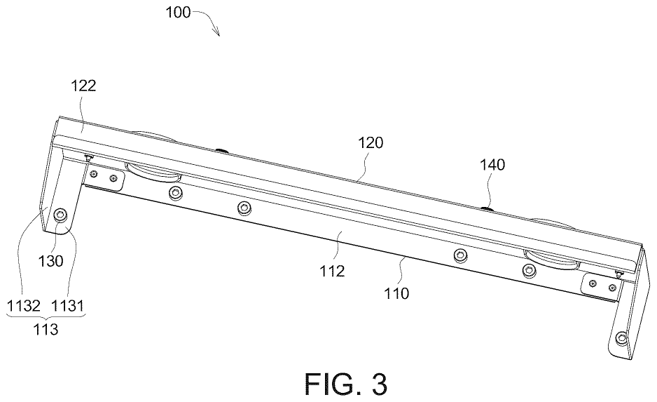

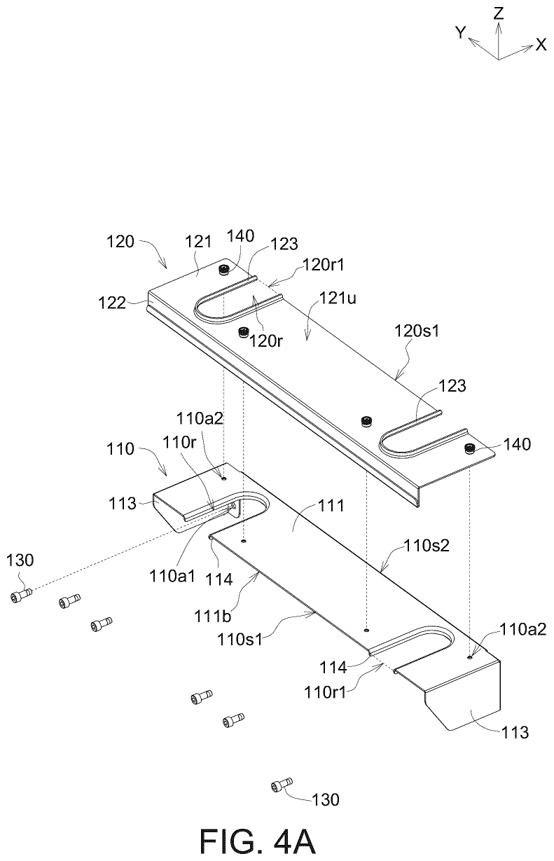

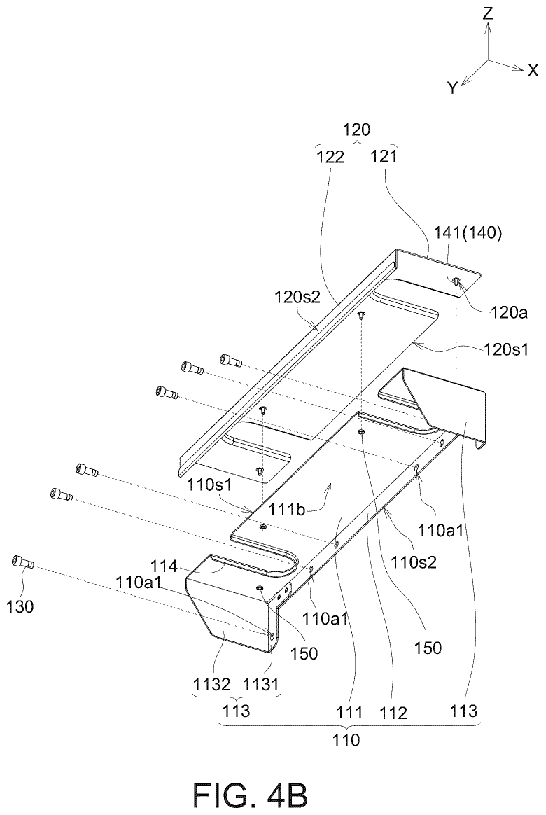

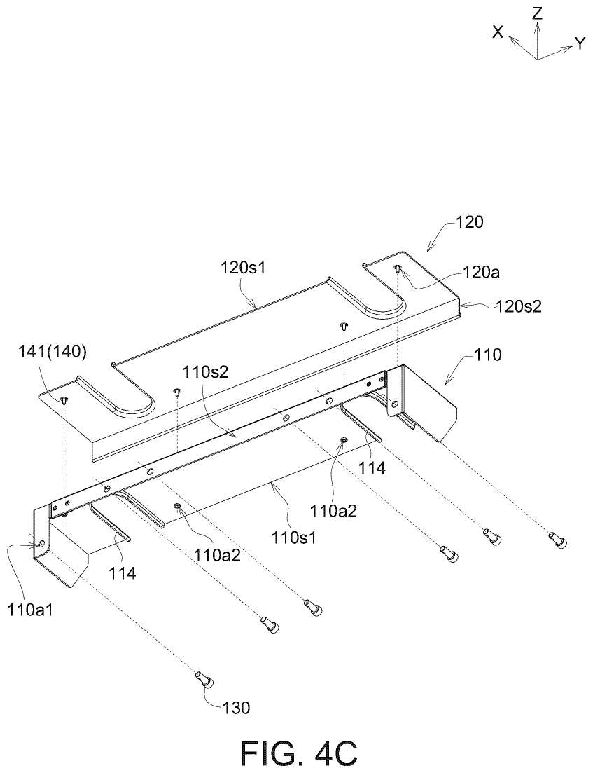

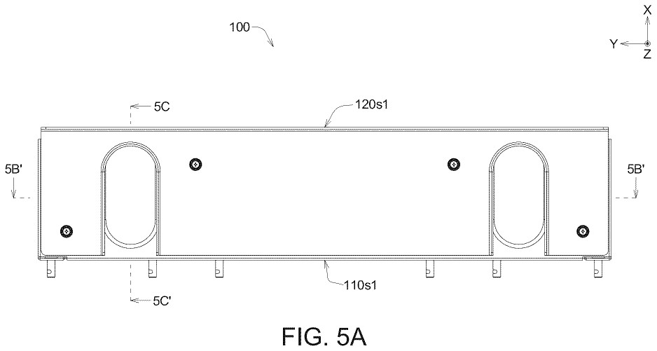

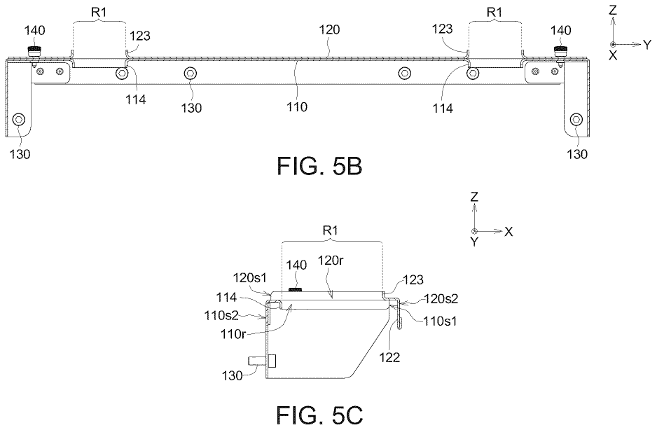

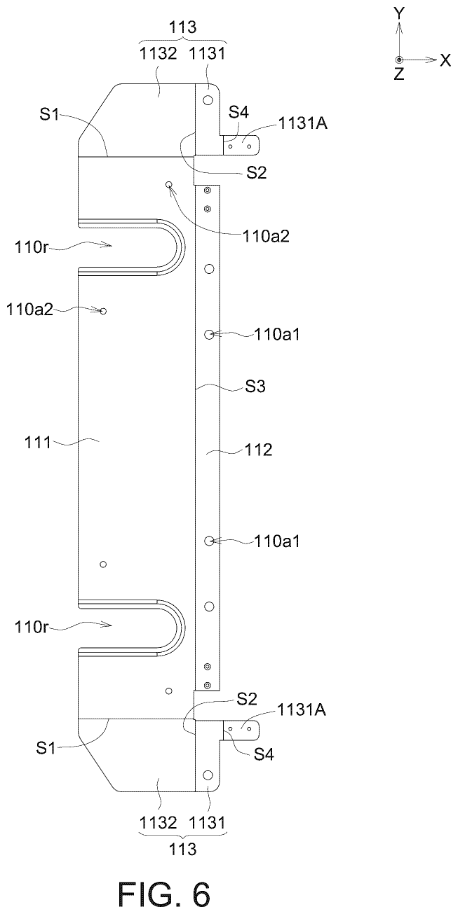

Referring to FIGS. 3, 4A to 4C, 5A to 5C and 6. FIG. 3 illustrates a schematic diagram of the pipe limiting device 100 in FIG. 2 from another viewing angle. FIGS. 4A to 4C illustrate schematic diagrams of exploded views of the pipe limiting device 100 in FIG. 2 at different viewing angles. FIG. 5A illustrates a schematic diagram of a front view of the pipe limiting device 100 in FIG. 2 as viewed along the −Z-axis. FIG. 5B illustrates a schematic diagram of a cross-sectional view of the pipe limiting device 100 in FIG. 5A along a direction 5B-5B′. FIG. 5C illustrates a schematic diagram of a cross-sectional view of the pipe limiting device 100 in FIG. 5A along a direction 5C-5C′. FIG. 6 illustrates a schematic diagram of an expanded view of a first limiting element 110 in FIG. 3.

As shown in FIGS. 2 and 4A to 4C, the pipe limiting device 100 includes the first limiting element (for example, a first position-limiting element) 110, a second limiting element (for example, a second position-limiting element) 120, at least one first fixing element 130, at least one second fixing element 140 and at least one third fixing element 150. The first limiting element 110 has at least one first limiting hole 110r. The second limiting element 120 has at least one second limiting hole 120r and is detachably fixed to the first limiting element 110. The first limiting hole 110r partially overlaps with the second limiting hole 120r. The pipe may pass through an overlapping area R1 (the overlapping area R1 is shown in FIG. 5B) where the first limiting hole 110r and the second limiting hole 120r overlap, so as to be constrained by the pipe limiting device 100.

As shown in FIGS. 4A to 4C and 5C, the first limiting element 110 has a first lateral surface 110s1 and a second lateral surface 110s2 opposite to the first lateral surface 110s1. The second limiting element 120 has a third lateral surface 120s1 and a fourth lateral surface 120s2 opposite to the third lateral surface 120s1. When the first limiting element 110 and the second limiting element 120 are assembled, the second lateral surface 110s2 is closer to the third lateral surface 120s1 than the first lateral surface 110s1, and the fourth lateral surface 120s2 is closer to the first lateral surface 110s1 than the third lateral surface 120s1.

As shown in FIG. 4A, the first limiting hole 110r extends to the first lateral surface 110s1 to form a first opening 110r1, so that the pipe may enter or exit the first limiting hole 110r of the first limiting element 110 through the first opening 110r1. The second limiting hole 120r extends to the third lateral surface 120s1 to form a second opening 120r1, so that the pipe may enter or exit the second limiting hole 120r of the second limiting element 120 through the second opening 120r1.

As shown in FIGS. 4A, 5B and 5C, in an embodiment, the first limiting hole 110r does not extend to the second lateral surface 110s2, so that the pipe is constrained in the first limiting hole 110r and cannot removed from the first limiting element 110 in the +X-axis direction. In addition, the second limiting hole 120r does not extend to the fourth lateral surface 120s2, so that the pipe is constrained in the second limiting hole 120r and cannot be separated from the second limiting element 120 in the −X-axis direction. When the first limiting element 110 is combined with the second limiting element 120, the first limiting hole 110r and the second limiting hole 120r at least partially overlap to form the overlapping area R1, and the pipe may be constrained in the overlapping area R1.

As shown in FIG. 4B, the first limiting element 110 includes an upper plate 111, at least one first lateral plate 112 and at least one second lateral plate 113. In the present embodiment, there are, for example, two second lateral plates 113, which are respectively disposed on two opposite sides of the upper plate 111. In addition, the upper plate 111 has the aforementioned first lateral surface 110s1, and the first lateral plate 112 has the aforementioned second lateral surface 110s2. The upper plate 111 further has a lower surface 111b. The first lateral plate 112 and the second lateral plate 113 are connected to the lower surface 111b of the upper plate 111 and protrude relative to the lower surface 111b.

As shown in FIG. 4B, the second lateral plate 113 includes a first portion 1131 and a second portion 1132. The first portion 1131 and the first lateral plate 112 are located on the same side of the upper plate 111. The second portion 1132 is connected with (for example, intersects) the first portion 1131. For example, an included angle between the second portion 1132 and the first portion 1131 is 90 degrees, but may also be greater or less. In an embodiment, the upper plate 111, the first lateral plate 112, and the second lateral plate 113 may be perpendicular to each other. The first lateral plate 112 and the second lateral plate 113 partially overlap. For example, the first lateral plate 112 partially overlaps with the first portion 1131 of the second lateral plate 113. The first portion 1131 and the first lateral plate 112 abut against the cabinet body 11. A length of the first portion 1131 along the Z-axis direction is longer than a length of the first lateral plate 112 along the Z-axis direction, and accordingly it may increase the stability of the first limiting element 110 abutting against the cabinet body 11. The first limiting element 110 may be integrally formed. For example, the first limiting element 110 may be formed by bending a metal element, as shown in FIGS. 4A and 4B.

As shown in FIG. 4B, the first portion 1131 and the first lateral plate 112 may be fixed to each other. For example, an end 1131A of the first portion 1131 (the end 1131A is shown in FIG. 6) and the first lateral plate 112 may be fixed by at least one fixing element, wherein the fixing element is, for example, a rivet. Alternatively, the first portion 1131 and the first lateral plate 112 may be welded, clamped, or glued together, and the embodiment of the present invention does not limit the fixing method of the first portion 1131 and the first lateral plate 112.

As shown in FIG. 6, in the unfolded view of the first limiting element 110, there is a fold line S1 between the second lateral plate 113 and the upper plate 111, wherein the second lateral plate 113 and the upper plate 111 may be folded relative to the fold line S1. There is a fold line S2 between the first portion 1131 and the second portion 1132, wherein the first portion 1131 and the second portion 1132 may be folded relative to the fold line S2. There is a fold line S3 between the upper plate 111 and the first lateral plate 112, wherein the upper plate 111 and the first lateral plate 112 may be folded relative to the fold line S3. The end portion 1131A may be folded relative to a fold line S4. After the first limiting member 110 shown in FIG. 6 is folded, it forms the first limiting member 110 as shown in FIG. 3.

In an embodiment, at least two of the upper plate 111, the first lateral plate 112 and the second lateral plate 113 may be integrally formed. For example, a plate may be bent and/or stamped to form an integral structure. In terms of material, the first limiting element 110 may be formed of metal, such as SGCC (Steel Galvanized Cold Commercial).

As shown in FIG. 4B, the second limiting element 120 includes an upper plate 121 and a third lateral plate 122. The upper plate 121 has the aforementioned third lateral surface 120s1, and the third lateral plate 122 has the aforementioned fourth lateral surface 120s2. The third lateral plate 122 is connected to the upper plate 121 and intersects with the upper plate 121. For example, an included angle between the third lateral plate 122 and the upper plate 121 is 90 degrees, but may also be greater or less.

In an embodiment, the upper plate 121 and the third lateral plate 122 may be an integrally formed structure. For example, a plate may be bent and/or stamped to form an integral structure. In terms of material, the second limiting element 120 may be formed of metal, such as SGCC.

As shown in FIGS. 2 and 4A to 4C, the first fixing element 130 is detachably connected to the first limiting element 110 and is configured to fix the first limiting element 110 to the cabinet body 11. For example, the first limiting element 110 has at least one through hole 110a1. The first fixing element 130 has, for example, threads, and the cabinet body 11 has at least one screw hole 11a. The first fixing element 130 may pass through the through hole 110a1 and be screwed into the screw hole 11a of the cabinet body 11 to fix the relative position of the cabinet body 11 and the first limiting element 110. Due to the detachability of the first fixing element 130, the first limiting element 110 may be quickly detached from the cabinet body 11 and/or assembled to the cabinet body 11. The second limiting element 120 of the embodiment of the present invention may be fixed on the cabinet body 11 using the first fixing element 130, so that when the first limiting element 110 fixes the pipe, the pipe may be more secure and will not wobble.

As shown in FIGS. 4A to 4C, the second fixing element 140 is detachably connected to the third fixing element 150 to fix the relative position between the first limiting element 110 and the second limiting element 120. For example, the first limiting element 110 further has at least one fixing hole 110a2, and the second limiting element 120 has at least one through hole 120a. For example, the through hole 120a is formed on the upper plate 121. The second fixing element 140 is, for example, a rotatable fixing element, which may be constrained in the through hole 120a of the second limiting element 120. For example, the second fixing element 140 may rotate relative to the upper plate 121 but cannot be easily separated along the Z-axis direction. The third fixing element 150 may be disposed on the first limiting element 110. For example, the third fixing element 150 may be riveted to the first limiting element 110. The second fixing element 140 has a fastening pin 141. The fastening pin 141 may pass through the through hole 120a and the fixing hole 110a2 to be fixed to the third fixing element 150. The fastening pin 141 of the second fixing element 140 and the third fixing element 150 are, for example, in a tightly-fitted state, so that the first limiting element 110 and the second limiting element 120 do not move relative to each other. Due to the design of the rotatable fixing element, it enables the two limiting element to be easily disassembled during assembly. By the detachability of the second fixing element 140 relative to the third fixing element 150, the first limiting element 110 and the second limiting element 120 may be quickly separated and/or combined.

In an embodiment, the second fixing element 140 is, for example, a rotatable screw (for example, it may be rotated by hand) having a thread (for example, the fastening pin 141 has the thread), and the third fixing element 150 is, for example, a nut. The second fixing element 140 may pass through the through hole 120a and the fixing hole 110a2 and be screwed into the third fixing element 150 to fix the relative position of the first limiting element 110 and the second limiting element 120.

In the present embodiment, the third fixing element 150 and the second fixing element 140 may form a fixing module. The first limiting element 110 and the second limiting element 120 are fixed to each other through at least one fixing module.

As shown in FIGS. 4A to 4C, the first limiting element 110 further includes at least one first flange 114 which may be connected to an edge of the first limiting hole 110r and protrude relative to the lower surface 111b of the upper plate 111 of the first limiting element 110. The first flange 114 acts as a reinforcing rib which may increase the strength of the first limiting element 110. Similarly, the second limiting element 120 further includes at least one second flange 123 which may be connected to an edge of the second limiting hole 120r and protrude relative to the upper surface 121u of the upper plate 121 of the second limiting element 120. The second flange 123 acts as a reinforcing rib which may increase the strength of the second limiting element 120. Although not shown, the pipe may abut against the second flange 123. Taking the first pipe 12A as an example (FIG. 1A), the first pipe 12A includes a pipe body 12A1 and a flange 12A2. The pipe body 12A1 may pass through the first limiting hole 110r and the second limiting hole 120r, and the flange 12A1 of the first pipe 12A may abut against the second flange 123 of the second limiting element 120, and it may prevent the first pipe 12A from detaching from the pipe limiting device 100 in the −Z-axis direction. The second pipe element 12B, the third pipe element 12C and the fourth pipe element 12D include similar features with those of the first pipe element 12A, and thus will not be described in detail herein. The pipe limiting device of the embodiment of the present invention has only two elements (i.e., the first limiting element 110 and the second limiting element 120) to fix the pipe, and it may achieve the purpose of limiting movement of the pipe in the XY plane with a simple design.

As described above, the disclosed embodiment provides a pipe limiting device and a server cabinet using the same. The pipe limiting device is suitable for being detachably connected to the cabinet body of the server cabinet. In an embodiment, the pipe limiting device includes at least two elements, and each element has a limiting hole. When these elements are combined, these limiting holes of these elements at least partially overlap, so that the pipe may pass through the overlapping area to be constrained in the overlapping area. In an embodiment, one of these elements is detachably connected to the cabinet body of the server cabinet and/or these elements are detachably connected to each other, so that the pipe limiting device may be quickly assembled to the cabinet body and/or may be quickly disassembled from the cabinet body.

It will be apparent to those skilled in the art that various modifications and variations may be made to the disclosed embodiments. It is intended that the specification and examples be considered as exemplars only, with a true scope of the disclosure being indicated by the following claims and their equivalents.

What is claimed is:

1. A pipeline limiting device, adapted to be detachably connected to a cabinet body of a server cabinet, and the pipeline limiting device comprising:
a first limiting element having a first limiting hole; and
a second limiting element, having a second limiting hole and detachably fixed to the first limiting element;
wherein the first limiting hole and the second limiting hole partially overlap.

2. The pipeline limiting device as claimed in claim 1, further comprising:
a first fixing element detachably connected to the first limiting element and configured to fix the first limiting element to the cabinet body.

3. The pipeline limiting device as claimed in claim 1, further comprising:
a second fixing element; and
a third fixing element, disposed on the first limiting element;
wherein the second fixing element is detachably connected to the third fixing element for fixing the first limiting element and the second limiting element.

4. The pipeline limiting device as claimed in claim 1, wherein the first limiting element has a first lateral surface and a second lateral surface opposite to the first lateral surface, the second limiting element has a third lateral surface, and the second lateral surface is closer to the third lateral surface than the first lateral surface, the first limiting hole extends to the first lateral surface so that the first lateral surface has an opening, and the second limiting hole extends to the third lateral surface so that the third lateral surface has an opening.

5. The pipeline limiting device as claimed in claim 4, wherein the second limiting element further has a fourth lateral surface opposite to the third lateral surface, and the fourth lateral surface is closer to the first lateral surface than the third lateral surface, the first limiting hole does not extend to the second lateral surface, and the second limiting hole does not extend to the fourth lateral surface.

6. The pipeline limiting device as claimed in claim 1, wherein the first limiting element comprises:
an upper plate having a lower surface;
a first lateral plate connected to the lower surface; and
a second lateral plate connected to the lower surface;
wherein the first lateral plate and the second lateral plate partially overlap.

7. The pipeline limiting device as claimed in claim 6, wherein the second lateral plate comprises:
a first portion, wherein the first portion and the first lateral plate are located on the same side of the upper plate; and
a second portion connected with the first portion;
wherein the first portion partly overlaps with the first lateral plate.

8. The pipeline limiting device as claimed in claim 1, wherein the second limiting element comprises:
an upper plate; and
a third lateral plate connected to the upper plate;
wherein the upper plate is connected with the third lateral plate.

9. A server cabinet, comprising:
a cabinet body;
a pipeline limiting device detachably connected to the cabinet body and comprising:
a first limiting element having a first limiting hole; and
a second limiting element having a second limiting hole and detachably fixed to the first limiting element, wherein the first limiting hole and the second limiting hole partially overlap;
a pipe passing through an overlapping area where the first limiting hole and the second limiting hole overlap.

10. The server cabinet as claimed in claim 9, wherein the pipeline limiting device further comprises:
a first fixing element detachably connected to the first limiting element and configured to fix the first limiting element to the cabinet body.

11. The server cabinet as claimed in claim 9, wherein the pipeline limiting device further comprises:
a second fixing element; and
a third fixing element disposed on the first limiting element;
wherein the second fixing element is detachably connected to the third fixing element for fixing the first limiting element and the second limiting element.

12. The server cabinet as claimed in claim 9, wherein the first limiting element has a first lateral surface and a second lateral surface opposite to the first lateral surface, the second limiting element has a third lateral surface, and the second lateral surface is closer to the third lateral surface than the first lateral surface, the first limiting hole extends to the first lateral surface so that the first lateral surface has an opening, and the second limiting hole extends to the third lateral surface so that the third lateral surface has an opening.

13. The server cabinet as claimed in claim 12, wherein the second limiting element further has a fourth lateral surface opposite to the third lateral surface, and the fourth lateral surface is closer to the first lateral surface than the third lateral surface, the first limiting hole does not extend to the second lateral surface, and the second limiting hole does not extend to the fourth lateral surface.

14. The server cabinet as claimed in claim 9, wherein the first limiting element comprises:
an upper plate having a lower surface;
a first lateral plate connected to the lower surface; and
a second lateral plate connected to the lower surface;
wherein the first lateral plate and the second lateral plate partially overlap.

15. The server cabinet as claimed in claim 14, wherein the second lateral plate comprises:
a first portion, wherein the first portion and the first lateral plate are located on the same side of the upper plate; and
a second portion connected with the first portion;
wherein the first portion partly overlaps the first lateral plate.

16. The server cabinet as claimed in claim 9, wherein the second limiting element comprises:
an upper plate; and
a third lateral plate connected to the upper plate;
wherein the upper plate is connected with the third lateral plate.
